(19) United States
(12) Patent Application Publication
(10) Pub. No.: US 2025/0027578 A1
(43) Pub. Date: Jan. 23, 2025

(54) PENDULUM VALVE WITH CALIBRATION DEVICE

(71) Applicant: VAT HOLDING AG, Haag (CH)

(72) Inventors: David DÜNSER, Schnifis (AT); Christoph RHINER, Sax (CH); Günther KOLB, Satteins (AT); Severin ZELTNER, Rorschacherberg (CH)

(21) Appl. No.: 18/715,534

(22) PCT Filed: Nov. 30, 2022
(86) PCT No.: PCT/EP2022/083774

§ 371 Date: May 31, 2024

(30) Foreign Application Priority Data
Dec. 2, 2021 (DE) 10 2021 005 995.6

(51) Int. Cl. F16K 37/00; F16K 31/04; F16K 51/02

(52) U.S. Cl. CPC F16K 37/0041; F16K 31/042; F16K 51/02

(57) ABSTRACT

A pendulum valve includes a valve seat with a first sealing surface and a valve closure with a second sealing surface corresponding to the first sealing surface, wherein the valve closure is pivotably mounted about a pivot axis by means of a drive unit. The pendulum valve has a calibration surface and a position sensor for determining a distance between the position sensor and the calibration surface, wherein the position sensor is arranged with a fixed positional relationship relative to the valve seat and the calibration surface is connected to the valve closure and is movably arranged such that a position of the calibration surface and the distance between the position sensor and the calibration surface vary during a pivoting movement of the valve closure.

The invention relates to a pendulum valve with a calibration device and calibration functionality for compensating a bearing play in the pendulum valve.

In general, valves are designed to adjust the flow rate of a fluid in particular. With a valve, the flow can be permitted or completely shut off via a maximum valve opening cross-section. In addition, certain valve types offer the possibility of regulating a flow rate per unit of time, i.e. provide controllability of a fluid flow.

Vacuum valves are a specific type of valve. These are known from the prior art in various designs for regulating a volume or mass flow and/or for essentially gas-tight closure of a flow path that leads through an opening formed in a valve housing and are used in particular in vacuum chamber systems in the field of IC, semiconductor or substrate production, which must take place in a protected atmosphere, preferably without the presence of contaminating particles.

Such vacuum chamber systems comprise, in particular, at least one evacuable vacuum chamber provided for holding semiconductor elements or substrates to be processed or manufactured, which has at least one vacuum chamber opening through which the semiconductor elements or other substrates can be guided into and out of the vacuum chamber, and at least one vacuum pump for evacuating the vacuum chamber. For example, in a production system for semiconductor wafers or liquid crystal substrates, the highly sensitive semiconductor or liquid crystal elements pass sequentially through several process vacuum chambers in which the parts located within the process vacuum chambers are each processed by means of a processing device. Both during the processing process within the process vacuum chambers and during transportation from chamber to chamber, the highly sensitive semiconductor elements or substrates must always be in a protected atmosphere—in particular in an airless environment.

Peripheral valves are used to open and close a gas inlet or outlet and transfer valves are used to open and close the transfer openings of the vacuum chambers for inserting and removing the parts.

The vacuum valves through which semiconductor parts pass are referred to as vacuum transfer valves due to the described area of application and the associated dimensions, also as rectangular valves due to their mostly rectangular opening cross-section and also as slide valves, rectangular slide valves or transfer slide valves due to their usual mode of operation.

Peripheral valves are used in particular for controlling or regulating the gas flow between a vacuum chamber and a vacuum pump or another vacuum chamber. Peripheral valves are located, for example, inside a pipe system between a process vacuum chamber or a transfer chamber and a vacuum pump, the atmosphere or a further process vacuum chamber. The opening cross-section of such valves, also known as pump valves, is generally smaller than that of a vacuum transfer valve. As peripheral valves are not only used for the complete opening and closing of an opening, depending on the area of use, but also for controlling or regulating a flow by continuously adjusting the opening cross-section between a fully open position and a gas-tight closed position, they are also referred to as regulating valves. One possible peripheral valve for controlling or regulating the gas flow is the pendulum valve.

In a typical pendulum valve, as known for example from U.S. Pat. No. 6,089,537 (Olmsted), in a first step, a generally round valve plate is rotationally pivoted over a generally also round opening from a position releasing the opening to an intermediate position covering the opening. In the case of a slide valve, as described for example in U.S. Pat. No. 6,416,037 (Geiser) or U.S. Pat. No. 6,056,266 (Blecha), the valve plate, like the opening, is usually rectangular and is pushed linearly in this first step from a position releasing the opening into an intermediate position covering the opening. In this intermediate position, the valve plate of the pendulum or slide valve is located in a spaced-apart position opposite the valve seat enclosing the opening. In a second step, the distance between the valve plate and the valve seat is reduced so that the valve plate and the valve seat are pressed uniformly against each other and the opening is essentially closed in a gas-tight manner. This second movement preferably takes place essentially in a perpendicular direction to the valve seat.

Sealing can be achieved, for example, either via a sealing ring arranged on the closing side of the valve plate, which is pressed onto the valve seat surrounding the opening, or via a sealing ring on the valve seat, against which the closing side of the valve plate is pressed. Due to the two-step closing process, the sealing ring between the valve plate and the valve seat is subjected to hardly any shear forces that would destroy the sealing ring, as the movement of the valve plate in the second step is essentially in a straight line perpendicular to the valve seat.

Various sealing devices are known from the prior art, for example from U.S. Pat. No. 6,629,682 B2 (Duelli). A suitable material for sealing rings and seals in vacuum valves is, for example, fluororubber, also known as FKM, in particular the fluoroelastomer known under the trade name “Viton”, as well as perfluororubber, FFKM for short.

Various drive systems are also known from the prior art for achieving this combination of a rotational movement of the valve plate parallel across the opening in the case of a pendulum valve and a translational movement perpendicular to the opening in the case of a slide valve, for example from U.S. Pat. No. 6,089,537 (Olmsted) for a pendulum valve and from U.S. Pat. No. 6,416,037 (Geiser) for a slide valve.

The valve plate must be pressed onto the valve seat, particularly for vacuum applications, in such a way that both the required gas tightness within the entire pressure range is ensured and damage to the sealing medium, in particular the sealing material or sealing ring (e.g. O-ring), due to excessive pressure stress is avoided. In order to ensure this, known valves provide a pressure regulation of the valve plate depending on the pressure difference between the two valve plate sides. However, it is not always possible to guarantee uniform force distribution along the entire circumference of the sealing ring, particularly in the case of large pressure fluctuations or when changing from negative pressure to positive pressure or vice versa. In general, however, the aim is to decouple the sealing ring from support forces resulting from the pressure applied to the valve.

Since the above-mentioned valves are used, among other things, in the manufacture of highly sensitive semiconductor elements in a vacuum chamber, a corresponding sealing effect must also be reliably guaranteed for such vacuum chambers. The condition of the entire valve or, in particular, a sealing material or a sealing surface in contact with the sealing material during compression is of particular importance here. During the service life of a vacuum valve, changes to valve components can typically occur due to wear of the sealing material or the sealing surfaces as well as structural changes to the valve components, e.g. drive unit or valve rod, due to environmental influences (temperature, humidity, impacts, etc.).

The bearing of the valve closure or a drive shaft can also be a source of faults. This can result from the fact that the pendulum valve is assembled and calibrated in a certain position at the factory, but the installation position of the valve at the customer's premises differs from the assembly position. Due to a given bearing play, this change in position can result in a misalignment of the valve closure relative to the valve seat, particularly when the valve moves to the closing position.

The invention is therefore based on the object of providing an improved pendulum valve, in particular a vacuum pendulum valve, which reduces or avoids the above-mentioned disadvantages.

It is a further object of the invention to provide an improved pendulum valve which provides reliable sealing functionality in an installed state.

These objects are solved by the realization of the characterizing features of the independent claims. Features which further develop the invention in an alternative or advantageous manner can be found in the dependent claims.

The fundamental idea of the present invention is to provide a vacuum pendulum valve having a sensor for distance determination in such a way that a distance to a surface connected to a valve closure can be determined by means of the sensor and this distance can depend on a pivotably adjustable opening position of the closure and a spatial orientation of the valve, e.g. due to gravitational forces acting on the valve closure. The distance measurement can thus be used to calibrate the position of the valve closure and compensate for any offset from a target position.

The invention thus relates to a pendulum valve, in particular a vacuum pendulum valve, for regulating a volume or mass flow and/or for closing and opening a valve opening. The pendulum valve has a valve seat which defines the valve opening defining an opening axis and has a first sealing surface surrounding the valve opening. The valve seat can be formed on a valve housing, for example. In addition, a valve closure is provided, in particular a valve plate, for regulating the volume or mass flow and/or for gas-tight closure of the valve opening with a second sealing surface corresponding to the first sealing surface. The valve closure is mounted so that it can pivot about a pivot axis.

The pendulum valve also has a drive unit coupled to the valve closure, which is adapted to provide a pivoting movement of the valve closure about the pivot axis in such a way that the valve closure can be adjusted from an open position, in which the valve closure at least partially clears the valve opening, to a closed position, in which the valve closure is positioned in or above the valve opening and (completely) covers the opening cross-section of the valve opening, and back.

In the closed position, sealing contact between the first sealing surface and the second sealing surface can be achieved in particular by means of an interposed sealing material (e.g. a fluoropolymer sealing ring) and the valve opening can thus be sealed gas-tight.

The pendulum valve has a calibration surface and a position sensor for determining a distance between the position sensor and the calibration surface.

The position sensor is arranged with a fixed positional relationship relative to the valve seat. The calibration surface is connected to the valve closure and arranged so that it can move in such a way that the position of the calibration surface during a pivoting movement of the valve closure and the distance between the position sensor and the calibration surface vary.

In one embodiment, the position sensor can be designed as an optically measuring distance sensor, an inductive distance determination sensor or an acoustically measuring distance sensor.

Such an arrangement can therefore be used to determine a distance between the sensor and the calibration surface that is at least dependent on the position of the valve closure.

In one embodiment, the pendulum valve may have a coupling, wherein the coupling couples or connects the valve closure to the drive unit and the calibration surface is provided with the coupling or the valve closure.

In particular, the coupling may have a shaft and/or a gear or be designed as such, and the calibration surface may be provided as a stop connected to the coupling or formed with the coupling.

The calibration surface can therefore be arranged on a motor shaft or a movable element connected to the shaft, for example, and is thus moved accordingly when the valve closure is pivoted. In this way, a measurement of the distance from the calibration surface can be used to infer a position of the valve closure. In particular, an angular position of the closure about the pivot axis, i.e. a position of the closure with and between the open position and the closed position, can be determined. In other words, a current position of the valve closure relative to the valve seat can be determined using the determined distance between the position sensor and the calibration surface.

According to one embodiment, the pendulum valve can have a control and processing unit with at least one control functionality and one calibration functionality. The control functionality is adapted to control the pivoting movement of the valve closure. This can be used, for example, to control the opening and closing of the valve, but also any pressure control setting between the open position and the closed position.

The calibration functionality is configured in such a way that when it is executed, the distance between the calibration surface and the position sensor is determined as the calibration value and the calibration value is compared with a reference value and corresponding calibration information is generated.

In particular, the reference value can be provided as a reference distance between the calibration surface and the position sensor.

In particular, this reference distance can also provide or correspond to a distance between the calibration surface and the position sensor in a target closing position of the valve closure. In the target closing position, a projection of the first sealing surface and a projection of the second sealing surface onto a plane parallel to the first and/or second sealing surface are at least partially, in particular completely, superimposed.

In the target closing position, the first sealing surface and the second sealing surface can be arranged concentrically.

In the above embodiment, the valve closure can therefore be set to the target closing position, for example by means of the control and processing unit. In this case, it can be verified externally (not by a functionality of the valve itself, but e.g. by a user) that the valve closure or the second sealing surface is positioned accurately relative to the valve seat or the first sealing surface. A measurement can then be carried out with the position sensor in this target closing position and the distance value recorded in this way can be stored as a reference value. This process is preferably carried out during production of the valve.

In one embodiment, the calibration value is determined in the closing position of the valve closure as part of the calibration functionality. The closing position (also: actual closing position) corresponds to the position or attitude assumed by the closure element when the closure element is moved into the closing position solely by means of the control and processing unit. There is no further (external) verification of this position, but it is typically assumed that the desired closing position has been reached. The calibration value can accordingly provide or correspond to a distance between the calibration surface and the position sensor in this closing position of the valve closure which was approached in a controlled manner.

The calibration value can preferably be determined after the pendulum valve has been installed in a production facility (e.g. in a production line for semiconductors) or assembled there.

In one embodiment, the calibration information can correspond in particular to a deviation of the actual closing position from the target closing position. The calibration information can alternatively or additionally be a difference between the distance determined in the target closing position and the distance determined in the actual closing position.

According to one embodiment, the control functionality can be adapted as a function of the calibration information as part of the calibration functionality.

In particular, the calibration information can indicate a deviation of the calibration value from the reference value and the control functionality can be adapted in such a way that when the valve closure is pivoted into the closing position, the closing position thus achieved (actual closing position) corresponds to the target closing position.

According to the invention, the pendulum valve can be calibrated by first performing a reference measurement of the distance between the calibration surface and the sensor and then performing a calibration measurement of the distance between the calibration surface and the sensor. For this purpose, the control unit can be adjusted based on a comparison of the reference measurement and the calibration measurement.

The control functionality can be adapted in such a way that, as a result of the adaptation, the closure element can be moved into the closing position by means of the control functionality in such a way that a deviation of the distance that can be determined in the actual closing position from the distance that can be determined in the target closing position is reduced or avoided (eliminated). For this purpose, control parameters of the control functionality such as pivot duration, pivot speed, pivot angle, motor current, etc. can typically be adjusted.

In one embodiment, the pendulum valve can have a separating device for separating a process atmosphere area from an outer atmosphere area. In particular, this relates to a design of the pendulum valve as a vacuum pendulum valve.

The process atmosphere area is to be understood in particular as an area that can be defined by a process chamber (vacuum chamber). In this area, a process atmosphere, in particular a vacuum, can be produced for processing substrates (e.g. semiconductors). Components intended for this area must meet increased requirements, e.g. with regard to material resistance. Accordingly, the external atmosphere area is to be understood in particular as an area in which normal atmospheric conditions are present, e.g. room air.

The drive unit can be assigned at least partially, in particular completely, to the external atmosphere area and the valve closure, in particular, to the process atmosphere area.

The separating device of the valve can be formed by a bellows, for example. The bellows can be provided inside the valve housing or the drive unit, for example.

A valve known from the prior art and described, for example, in U.S. Pat. No. 6,772,989 has a valve body with two connections, a valve seat arranged in a flow path connecting the two connections in the flow chamber and an opening opposite the valve seat. A piston of a pneumatic cylinder system is arranged in a valve cover closing the opening, which drives a valve plate that opens and closes the valve seat via a valve rod. The valve cover is attached to the opening in a gas-tight manner by a bellows plate. The two ends of a bellows, which surrounds the valve rod, are attached gas-tight to the inner edge surface of the bellows plate and to the valve plate. On the surface facing the valve seat, the valve plate has an annular retaining groove in which a sealing ring is arranged.

Transferred to the pendulum valve according to the invention, the valve rod can be embodied by the coupling (e.g. gear or shaft).

The valve housing of the pendulum valve is made of aluminum or stainless steel, for example, or coated on the inside with aluminum or another suitable material, while the valve plate and bellows are usually made of steel. The bellows, which can be expanded and compressed along its longitudinal axis within the adjustment range of the plate, seals the flow chamber airtight from the valve rod and the actuator. Two main types of bellows are used. One is the diaphragm bellows and the other is the shaft bellows, which is distinguished from the diaphragm bellows by the fact that it has no weld seams and is easier to clean, but has a smaller maximum stroke.

The invention also relates to a method for calibrating a pendulum valve described above. The method comprises at least the following steps of:
determining a distance between the calibration surface and the position sensor as a calibration value,
comparing the calibration value with a reference value, wherein the reference value provides a reference distance (nominal distance) between the calibration surface and the position sensor,
providing calibration information indicating a deviation of the calibration value from the reference value, and
adapting a control of the pivoting movement of the valve closure based on the calibration information in such a way that when the valve closure is pivoted into the closing position, the closing position thus achieved corresponds to a target closing position.

The invention also relates to a computer program product comprising program code which is stored on a machine-readable carrier, in particular a control and processing unit of a pendulum valve described above, or computer data signal embodied by an electromagnetic wave, for carrying out or controlling the steps of the above method. The computer program product may comprise an algorithm designed for this purpose.

The valve according to the invention is described in more detail below by way of purely exemplary embodiments shown schematically in the drawings. Identical elements are marked with the same reference signs in the figures. The embodiments described are generally not shown to scale and are not to be understood as a limitation.

The drawings show in detail:

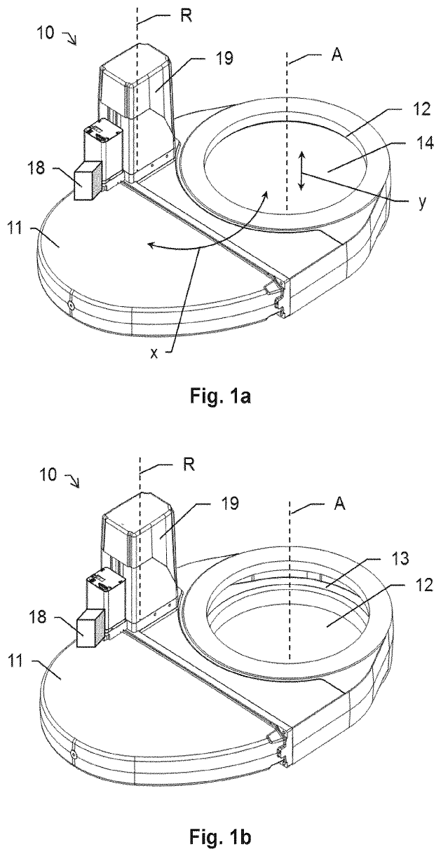

FIGS. 1a-b show an embodiment of a vacuum pendulum valve according to the invention;

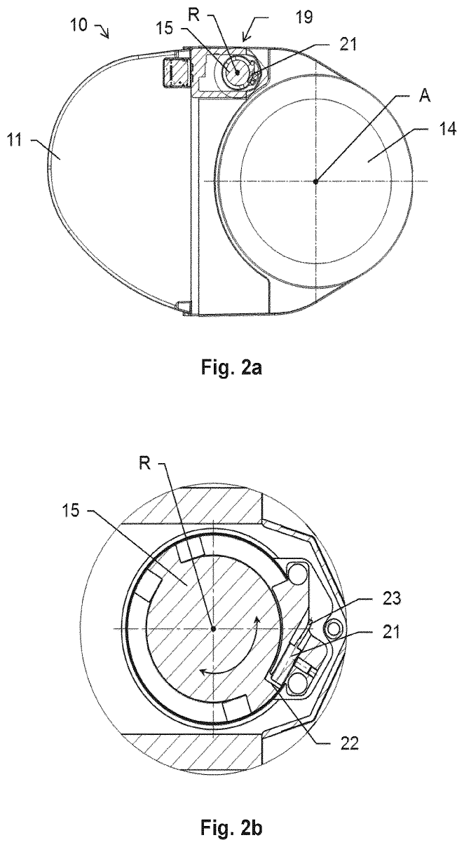

FIGS. 2a-b show a cross-sectional view of an embodiment of a pendulum valve according to the invention in the closed position and an enlarged section of the pendulum valve in the area of the drive unit;

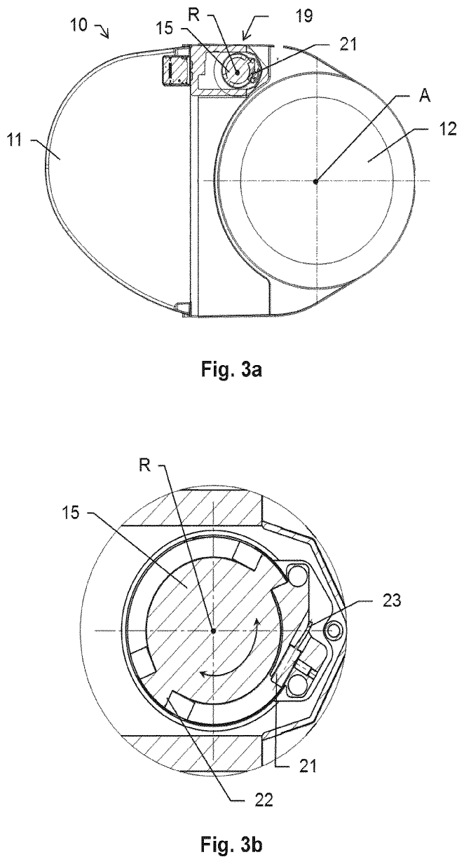

FIGS. 3a-b show a cross-sectional view of an embodiment of a pendulum valve according to the invention in the open position and an enlarged section of the pendulum valve in the area of the drive unit; and

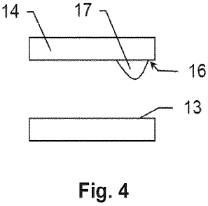

FIG. 4 shows a cross-section in the edge area of the valve closure of a valve according to the invention.

FIGS. 1a and 1b show an embodiment of a vacuum pendulum valve 10 according to the invention. The valve 10 is designed in particular for regulating a mass flow and for essentially gas-tight interruption of a flow path. The valve 10 has a valve housing 11 which has an opening 12. Here the opening 12 has a circular cross-section, for example. The opening 12 is enclosed by a valve seat. This valve seat has a first sealing surface 13 which faces axially in the direction of a valve closure 14 (valve plate) in a closed position and extends transversely to an opening axis A and has the shape of a circular ring, which in the example shown is formed on the valve housing 11.

The valve closure 14 is pivotable about an axis of rotation R and can be adjusted essentially parallel to the opening axis A. In a closed position S (FIG. 1a) of the valve plate 14 (valve closure), the opening 12 is covered by the valve plate 14, which has a second sealing surface with sealing material. An open position of the valve 10 is shown in FIG. 1b. The valve closure 14 is pivoted about the pivot axis in such a way that the opening 12 is completely uncovered and the valve closure 14 is present in the valve housing 11.

The valve closure 14 is connected to a drive unit 19 (e.g. motor) via an arm (not shown) arranged on the side of the closure and extending perpendicular to the opening axis. In the closed position (FIG. 1a) of the valve plate 14, this arm is located outside the geometrically projected opening cross-section of the opening 12 along the opening axis A.

The drive 19 is designed by using a corresponding gear in such a way that the valve plate 14—as is usual with a pendulum valve—can be pivoted between an open position (FIG. 1b) and a closed position (FIG. 1a) by means of a transverse movement x by the drive 19 transverse to the opening axis A and substantially parallel across the cross-section of the opening 12 and perpendicular to the opening axis A in the form of a pivoting movement about the pivot axis R.

The closed position is to be understood as a state of the valve closure 14 in which the valve closure 14 at least covers the opening 12. In the closed position, the valve closure 14 can be present without contact relative to the valve seat (intermediate position; no complete sealing of the opening is provided by contacting the sealing material with both the first and the second sealing surface). In the closed position, however, gas-tight closure of the opening 12 (sealing position) can also be provided. In this case, the sealing material is in contact with the first sealing surface 13 on the part of the valve closure 14. For this purpose, the valve closure 14 is linearly displaceable by the drive 19 in accordance with a longitudinal movement y along the opening axis A.

As already mentioned, the valve plate 14 is positioned in the open position in a dwell section arranged laterally next to the opening 12, so that the opening 12 and the flow path are unobstructed. In the intermediate position, the valve plate 14 is positioned at a distance above the first opening 12 and covers the opening cross-section of the opening 12. In the sealed position, the opening 12 is closed gas-tight and the flow path is interrupted by a gas-tight contact between the valve closure 14 and the sealing surface 13 of the valve seat (by means of the sealing material).

In order to enable automated and controlled opening and closing of the valve, the valve can have an electronic control and processing unit 18 which is designed and connected to the drive 19 in such a way that the valve plate 14 can be adjusted accordingly for gas-tight closure of a process volume or for regulating an internal pressure of this volume. Such a control and processing unit 18 can, together with the valve, a process chamber and, for example, a peripheral unit (e.g. gas inlet unit), form the core of a vacuum processing device, as used, for example, in semiconductor production.

The position of the valve plate 14 can be variably adjusted using a regulating variable and an output control signal. The input signal can be information, e.g. about a current pressure state in the process volume connected to the valve. In addition, the regulator can be provided with a further input variable, e.g. a mass inflow into the volume. Using these variables and a specified target pressure that is to be set or achieved for the volume, a regulated setting of the valve can then be carried out using the time of a regulating cycle, so that a mass outflow from the volume can be regulated over time by means of the valve. A vacuum pump is typically provided downstream of the valve for this purpose, i.e. the valve is arranged between the process chamber and the pump. This allows a desired pressure curve to be regulated.

By adjusting the position of the valve closure 14, a respective opening cross-section for the valve opening 12 can be set and thus the possible amount of gas that can be evacuated from the process volume per unit of time can be set. For this purpose, the valve closure 14 can have a shape that deviates from a circular shape, in particular in order to achieve a media flow that is as laminar as possible.

To set the opening cross-section, the valve plate 14 can be adjusted by the control and processing unit 18 from the open position to the intermediate position by means of the transverse movement x by the drive 19 and from the intermediate position to the sealing position by means of the longitudinal movement y by the drive 19. To open the flow path completely, the valve plate 14 can then be moved by the control unit from the sealing position to the intermediate position by means of the longitudinal movement y and from there from the intermediate position to the open position by means of the transverse movement x.

In the present exemplary embodiment, the drive 19 is designed as an electric motor, with the gear being switchable in such a way that driving the drive 19 causes either the transverse movement x or the longitudinal movement y. The drive 19 and the gear are electronically driven by the regulation. Gears of this type, in particular with gate-type gears, are known from the prior art. It is also possible to use several drives to produce the transverse movement x and the longitudinal movement y, with the control unit taking over the control of the drives. In such an embodiment, the multiple drives are to be understood as parts of the drive unit.

Precise regulation or adjustment of the flow rate with the described pendulum valve is possible not only by pivoting adjustment of the valve plate 14 between the open position and the intermediate position by means of the transverse movement x, but above all by linear adjustment of the valve plate 14 along the opening axis A between the intermediate position and the sealing position by means of the longitudinal movement y. The described pendulum valve can be used for precise regulating tasks.

Both the valve plate 14 and the valve seat each have a sealing surface—a first and a second sealing surface. The second sealing surface on the valve closure also has a seal. This seal can, for example, be vulcanized onto the second sealing surface as a polymer by means of vulcanization. Alternatively, the seal can, for example, be designed as an O-ring in a groove of the valve closure. A sealing material can also be bonded to the valve closure and thereby form the seal. In an alternative embodiment, the seal can be arranged on the side of the valve seat, in particular on the first sealing surface 13. Combinations of these embodiments are also conceivable.

The control and processing unit 18 may, for example, be of an integrated design with the vacuum valve, i.e. the control and processing unit is provided by and with the valve. Alternatively, the control and processing unit may be physically separate from the valve 10 and may, for example, be in a wireless communication connection with the drive unit 19 and/or the position sensor 21.

The pendulum valve 10 also has a position sensor 21, which is designed to determine a distance between the position sensor 21 and a calibration surface 22. The position sensor 21 is arranged with a fixed positional relationship relative to the valve seat or on the valve housing 11. The calibration surface 22 is connected to the valve closure 14 and is movably arranged in such a way that a position of the calibration surface 22 and the distance between the position sensor 21 and the calibration surface 22 vary accordingly during a pivoting movement of the valve closure 14.

The position sensor 21 can be designed as an inductive or optical sensor for determining a distance to a target (here: calibration surface 22).

FIG. 2a shows a cross-sectional view (section through a plane orthogonal to the opening axis A) of the pendulum valve 10 shown in FIG. 1a in the closed position. FIG. 2b shows a section of the valve 10 from FIG. 2a in the area of the drive unit 19.

In the example shown, the position sensor 21 is permanently connected to a part of the drive unit 19, e.g. to the housing. In addition, an electrical connection 23 of the sensor is shown, in particular a cable, for supplying power to the sensor 21 and/or for transmitting measurement signals from the sensor 21 to the control and processing unit 18. In an alternative embodiment, the connection 23 can be omitted and, for example, a sensor-integrated power supply (e.g. battery or rechargeable battery) and wireless communication (e.g. WLAN, WiFi, Bluetooth, NFC, etc.) can be provided.

The position sensor 21 is adapted to determine a distance to the calibration surface 22. The calibration surface 22 is assigned to a movable coupling 15 (pivot element). The pivot element 15 is rotatably mounted about the pivot axis R and can be driven by means of the drive unit 19. In particular, the coupling 15 has a shaft of the drive unit 19, in particular of a motor of the drive unit 19, or a gear of the drive unit 19, or is designed as such or as such. The calibrating surface 22 can be provided as a stop connected to the coupling 15.

The coupling 15 couples the valve closure 14 to the drive unit 19 in such a way that the mobility of the valve closure 14 is provided by the drive unit 19 through the coupling 15.

In one embodiment, the coupling 15 can be the motor shaft of the drive unit 19 provided as an electric motor.

In the closed position shown in FIGS. 2a and 2b, there is a first distance between the position sensor 21 and the surface 22. In the open position shown in FIGS. 3a and 3b, there is a second distance between the position sensor 21 and the surface 22. The second distance is greater than the first distance.

The coupling 15 provided for providing the mobility of the valve closure 14 typically has at least a very small bearing play relative to the valve seat due to the manufacturing process. Play is understood here to be a manufacturing or application-related freedom of movement in which a mechanical component can move freely against or with another component of the assembly or functional unit during or after assembly.

In the design and manufacture of a vacuum valve in particular, the tension between large play in conjunction with smooth movement of the valve closure 14 and small play in conjunction with high positioning accuracy of the valve closure 14 must be taken into account. Since precise positioning of the valve closure 14 relative to the valve seat is important both for reliable sealing of the valve opening 12 and to prevent excessive or premature wear of the sealing material, a small bearing play is typically preferable. However, it is not possible to completely avoid the play simply to avoid large frictional forces in the bearing.

When manufacturing or assembling the vacuum valve 10, the valve components are matched and assembled in such a way that, in particular, precise sealing of the valve opening 12 can be provided by a corresponding movement of the valve closure 14. The calibration is thus typically performed in such a way that the first and second sealing surfaces are precisely superimposed in the closed position of the valve closure 14. However, this assembly and adjustment (calibration) of the valve 10 is always carried out in a specific alignment (calibration alignment) of the valve 10, e.g. in a horizontal alignment (see FIGS. 1a and 1b). The gear play can then have a detrimental effect on the functional reliability of the valve 10 if the valve is installed in an orientation (installation position) that deviates from the calibration orientation.

Due in particular to the mass of the valve closure 14, the weight force caused by this acts in a certain direction depending on the valve orientation and therefore also differently on the coupling 15 (in particular the gear and the bearing). Inertia forces caused by the movement of the closure 14 also act in different ways, in particular in different directions.

If the vacuum valve 10 is installed in an installation position that differs from the calibration orientation, this can result in the valve closure 14 assuming a position that deviates from the calibrated closing position when the closing position is approached.

According to the invention, such a deviation can be detected by means of a distance measurement using the position sensor 21 and compensated for by the control system. The advantage of this approach also lies in the fact that for a calibration of the valve in such an installation orientation, no complex mechanical intervention is required. Instead, the calibration can be performed by means of the valve control.

According to the invention, a reference value can first be determined for a distance between the calibration surface 22 and the sensor 21 in the calibration orientation in the closing position. This reference value can accordingly represent a target position (angular position about the pivot axis R) for the valve closure 14 for reaching the closing position. In other words, the valve closure 14 is then present as a distance in the target closing position when the reference value is determined. This determination of the reference value is preferably carried out in the factory as part of the production of the vacuum valve.

In addition, a calibration value for the vacuum valve can be determined. The calibration value can be a distance between the calibration surface 22 and the position sensor 21, wherein the valve closure 14 has been moved into a closed position. This means that the valve closure 14 is pivoted into the closed position (open-loop) by activating the drive unit by means of the control and processing unit. The end position thus reached by the valve closure 14 corresponds in particular to predefined control values. The calibration value can preferably be determined by the customer, e.g. after the valve has been installed in a production line.

As mentioned above, there may be a deviation between the predetermined reference value and the calibration value when determining the calibration value, e.g. due to a different valve orientation or e.g. due to a repositioning of the motor (e.g. on the other valve side). Such a deviation can be derived and provided as calibration information by comparing the two values.

In one embodiment, the control functionality for controlling the drive unit can be adapted based on the calibration information. Specifically, corresponding control parameters such as an end position (angular position around the pivot axis R), motor current, pivot duration, etc. can be adapted in such a way that the valve closure 14 assumes the target closing position corresponding to the reference value when the closing position is approached, even in the installation position. This makes it easy to calibrate the position after the valve has been installed (at the customer's premises), thus ensuring the reliability of the sealing effect and the precision of the corresponding positioning of the sealing surfaces in the closing position.

Such a calibration can be carried out, for example, after the valve 10 has been installed and/or at certain intervals, e.g. after a certain number of opening and closing movements or after a certain period of operation.

FIG. 3a shows a cross-sectional view (section through a plane orthogonal to the opening axis A) of the pendulum valve 10 shown in FIG. 1b in the open position. FIG. 3b shows a section of the valve 10 from FIG. 3a in the area of the drive unit 19.

A distance between the calibration surface 22 and the position sensor 21 is greater than the distance in the closed position. Corresponding to the calibration of the position of the valve closure 14 for the closed position described above, such a calibration can also be carried out for the open position in an analogous manner. For this purpose, a distance in a target open position is determined as the reference value and the distance after pivoting the shutter 14 into the open position is determined as the calibration value.

FIG. 4 shows a cross-section in the edge area of the valve closure 14 (valve plate) in the closed position. The valve plate 14 has a second sealing surface 16. A seal 17 (sealing material) is vulcanized onto the second sealing surface 16 or connected to it by means of an alternative method. The second sealing surface 16 or the sealing material 17 is located in an opposite position to the first sealing surface 13 of the valve seat. The valve closure 14 is shown in an intermediate position representing the closed position, wherein the sealing material 16 is not (yet) (or no longer) in contact with the first sealing surface 13, but the valve opening is covered by the valve closure 14.

It should be understood that the figures shown are only schematic representations of possible exemplary embodiments. The various approaches can also be combined with each other and with devices and methods of the prior art.

1. A pendulum valve for regulating a volume or mass flow and/or for closing and opening a valve opening, comprising:
a valve seat which defines the valve opening defining an opening axis and has a first sealing surface surrounding the valve opening,
a valve closure for regulating the volume or mass flow and/or for gas-tight closure of the valve opening with a second sealing surface corresponding to the first sealing surface, wherein the valve closure is pivotably mounted about a pivot axis, and
a drive unit coupled to the valve closure, which is adapted to provide a pivoting movement of the valve closure about the pivot axis in such a way that the valve closure can be adjusted from
an open position, in which the valve closure at least partially clears the valve opening, to
a closed position, in which the valve closure is positioned above the valve opening and covers the opening cross-section of the valve opening, and back,
wherein
the pendulum valve has
a calibration surface and
a position sensor for determining a distance between the position sensor and the calibration surface,
wherein
the position sensor is arranged with a fixed positional relationship relative to the valve seat, and
the calibration surface is connected to the valve closure and is movably arranged in such a way that a position of the calibration surface and the distance between the position sensor and the calibration surface vary during a pivoting movement of the valve closure.

2. The pendulum valve according to claim 1, wherein
the pendulum valve has a coupling, wherein
the coupling couples the valve closure to the drive unit and
the calibration surface is provided on the coupling or the valve closure.

3. The pendulum valve according to claim 1, wherein
the coupling has a shaft and/or a gear and the calibration surface is provided as a stop connected to the coupling or formed with the coupling.

4. The pendulum valve according to claim 1,
wherein
the coupling is provided as a pivot element designed to rotate about a pivot axis.

5. The pendulum valve according to claim 1,
wherein
the pendulum valve has a control and processing unit with a control functionality and a calibration functionality, wherein
the control functionality is adapted to control the pivoting movement of the valve closure and
the calibration functionality is configured in such a way that when it is executed,
the distance between the calibration surface and the position sensor is determined as the calibration value, and
the calibration value is compared with a reference value and corresponding calibration information is generated.

6. The pendulum valve according to claim 5,
wherein
the reference value is provided as a reference distance between the calibration surface and the position sensor.

7. The pendulum valve according to claim 6,
wherein
the reference distance provides a distance between the calibration surface and the position sensor in a target closing position of the valve closure, wherein in the target closing position a projection of the first sealing surface and a projection of the second sealing surface onto a plane parallel to the first sealing surface are at least partially superimposed.

8. The pendulum valve according to claim 7,
wherein
the first sealing surface and the second sealing surface are arranged concentrically in the target closing position.

9. The pendulum valve according claim 5,
wherein
the reference value provides an angular position about the pivot axis for the valve closure.

10. The pendulum valve according to claim 5,
wherein
the calibration value is determined in the closing position of the valve closure.

11. The pendulum valve according to claim 5,
wherein
the control functionality is adapted as a function of the calibration information as part of the calibration functionality.

12. The pendulum valve according to claim 11,
wherein
the calibration information indicates a deviation of the calibration value from the reference value, and
the control functionality is adapted in such a way that when the valve closure is pivoted into the closing position, the closing position thus achieved corresponds to the target closing position.

13. The pendulum valve according to claim 5,
wherein
a current position of the valve closure relative to the valve seat can be determined on the basis of the determined distance between the position sensor and the calibration surface.

14. A method for calibrating a pendulum valve according to claim 1, comprising:
determining a distance between the calibration surface and the position sensor as a calibration value;
comparing the calibration value with a reference value, wherein the reference value provides a reference distance between the calibration surface and the position sensor;
providing calibration information indicating a deviation of the calibration value from the reference value; and
adapting a control of the pivoting movement of the valve closure based on the calibration information in such a way that when the valve closure is pivoted into closing position, the closing position thus achieved corresponds to a target closing position.

15. A computer program product comprising program code which is stored on a control and processing unit of a pendulum valve according claim 5 for carrying out or controlling a method comprising:
determining a distance between the calibration surface and the position sensor as a calibration value;
comparing the calibration value with a reference value, wherein the reference value provides a reference distance between the calibration surface and the position sensor;
providing calibration information indicating a deviation of the calibration value from the reference value; and
adapting a control of the pivoting movement of the valve closure based on the calibration information in such a way that when the valve closure is pivoted into closing position, the closing position thus achieved corresponds to a target closing position.
